(19) United States
(12) Patent Application Publication
(10) Pub. No.: US 2024/0224420 A1
(43) Pub. Date: Jul. 4, 2024

(54) PRINTED CIRCUIT BOARD

(71) Applicant: SAMSUNG ELECTRO-MECHANICS CO., LTD., Suwon-si (KR)

(72) Inventors: Hyun Woo KWON, Suwon-si (KR); Jong Eun PARK, Suwon-si (KR)

(73) Assignee: SAMSUNG ELECTRO-MECHANICS CO., LTD., Suwon-si (KR)

(21) Appl. No.: 18/212,867

(22) Filed: Jun. 22, 2023

(30) Foreign Application Priority Data
Dec. 29, 2022 (KR) 10-2022-0188460

(51) Int. Cl. H05K 1/02; H05K 1/11; H05K 3/46

(52) U.S. Cl. CPC H05K 1/0298; H05K 1/111; H05K 1/115; H05K 3/4602

(57) ABSTRACT

A printed circuit board includes a first substrate portion including a first insulating layer, a second insulating layer disposed on the first insulating layer, and a third insulating layer disposed on the second insulating layer; and a second substrate portion disposed on the first substrate portion and including a first fine insulating layer as a build-up insulating layer on an uppermost side of the first substrate portion and the second substrate portion. A thickness of the first insulating layer, a thickness of the second insulating layer, and a thickness of the third insulating layer are sequentially reduced. A thickness of the first fine insulating layer is lower than the thickness of the third insulating layer.

### CROSS-REFERENCE TO RELATED APPLICATION(S)

This application claims benefit of priority to Korean Patent Application No. 10-2022-0188460 filed on Dec. 29, 2022 in the Korean Intellectual Property Office, the disclosure of which is incorporated herein by reference in its entirety.

### TECHNICAL FIELD

The present disclosure relates to a printed circuit board.

Recently, to process amounts of data exponentially increased due to the development of artificial intelligence (AI) technology and the like, multi-chip packages, including memory chips such as High Bandwidth Memory (HBM) and processor chips such as a Central Processing Unit (CPU), a Graphics Processing Unit (GPU), an Application Special Specific Integrated Circuit (ASIC), a Field Programmable Gate Array (FPGA) and the like, have been used. In the substrate structure in which various chips are mounted on the substrate, research into reducing defects occurring during chip mounting and to improving yield is ongoing.

### SUMMARY

An aspect of the present disclosure is to provide a printed circuit board in which defects may be prevented in a printed circuit board on which electronic components, chips and the like are to be mounted.

An aspect of the present disclosure is to provide a printed circuit board on which a signal path may be more finely implemented.

An aspect of the present disclosure is to provide a method of manufacturing a printed circuit board, in which reliability may be improved.

According to an aspect of the present disclosure, a printed circuit board includes a first substrate portion including a first insulating layer, a second insulating layer disposed on the first insulating layer, and a third insulating layer disposed on the second insulating layer; and a second substrate portion disposed on the first substrate portion and including a first fine insulating layer as a build-up insulating layer on an uppermost side of the first substrate portion and the second substrate portion. A thickness of the first insulating layer, a thickness of the second insulating layer, and a thickness of the third insulating layer are sequentially reduced. A thickness of the first fine insulating layer is lower than the thickness of the third insulating layer.

According to an aspect of the present disclosure, a printed circuit board includes a first substrate portion including a first circuit layer, a second circuit layer disposed on an upper layer of the first circuit layer, and a third circuit layer disposed on an upper layer of the second circuit layer; and a second substrate portion disposed on the first substrate portion and including a first microcircuit layer as a build-up circuit layer on an uppermost side of the first substrate portion and the second substrate portion. A thickness of the first circuit layer, a thickness of the second circuit layer, and a thickness of the third circuit layer are sequentially reduced. A thickness of the first microcircuit layer is lower than a thickness of the third circuit layer.

According to an aspect of the present disclosure, a printed circuit board includes a first substrate portion and a second substrate portion disposed on the first substrate portion. The first substrate portion includes: a first insulating layer, a second insulating layer disposed on the first insulating layer, and a third insulating layer disposed on the second insulating layer, and a first via penetrating through the first insulating layer, a second via penetrating through the second insulating layer, and a third via penetrating through the third insulating layer. The second substrate portion includes: a first fine insulating layer as a build-up insulating layer on an uppermost side of the first substrate and the second substrate, and a second fine insulating layer disposed below the first fine insulating layer, and a first microvia penetrating through the second fine insulating layer. A width of an upper surface of the first via, a width of an upper surface of the second via, and a width of an upper surface of the third via sequentially decrease. A width of an upper surface of the first microvia is narrower than the width of the upper surface of the third via.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a schematic cross-sectional view of a printed circuit board according to an example; and

FIG. 4 is an enlarged cross-sectional view of a portion of the printed circuit board of FIG. 3.

### DETAILED DESCRIPTION

Hereinafter, the present disclosure will be described with reference to the accompanying drawings. The shapes and sizes of elements in the drawings may be exaggerated or reduced for clearer description.

### Electronic Device

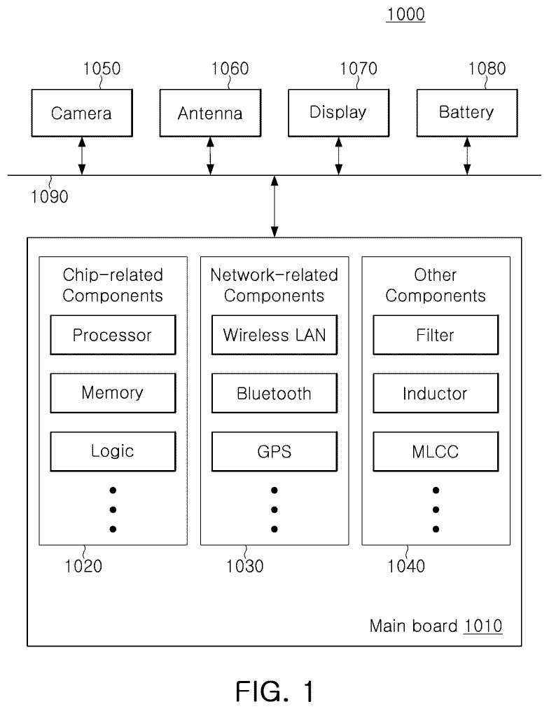

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to other electronic components to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related electronic components. In addition, the chip related components 1020 may be combined with each other. The chip-related components 1020 may be in the form of a package including the aforementioned chip or electronic component.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive elements in the form of chip components used for various other purposes, or the like. In addition, other components 1040 may be combined with each other, together with the chip related components 1020 or the network related components 1030 described above.

Depending on a type of the electronic device 1000, the electronic device 1000 may include other electronic components that may or may not be physically or electrically connected to the mainboard 1010. These other electronic components may include, for example, a camera module 1050, an antenna module 1060, a display device 1070, a battery 1080, and the like, but are not limited thereto. These other electronic components may also be an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. These other components may also include other electronic components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

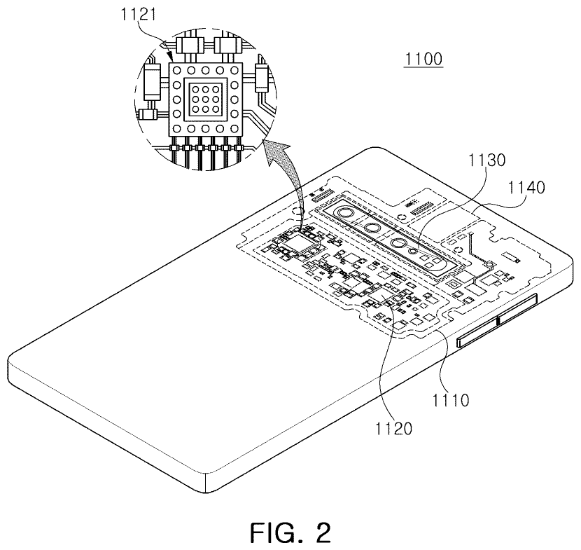

FIG. 2 is a schematic perspective view illustrating an example of an electronic device.

Referring to the drawing, the electronic device may be, for example, a smartphone 1100. A motherboard 1110 is accommodated inside the smartphone 1100, and various components 1120 are physically and/or electrically connected to the motherboard 1110. In addition, other components that may or may not be physically and/or electrically connected to the motherboard 1110, such as the camera module 1130 and/or the speaker 1140, are accommodated therein. Some of the components 1120 may be the aforementioned chip-related components, for example, the component package 1121, but are not limited thereto. The component package 1121 may be in the form of a printed circuit board on which electronic components including active components and/or passive components are surface mounted. Alternatively, the component package 1121 may be in the form of a printed circuit board in which active components and/or passive components are embedded. On the other hand, the electronic device is not necessarily limited to the smartphone 1100, and as described above, may be other electronic devices, of course.

### Printed Circuit Board

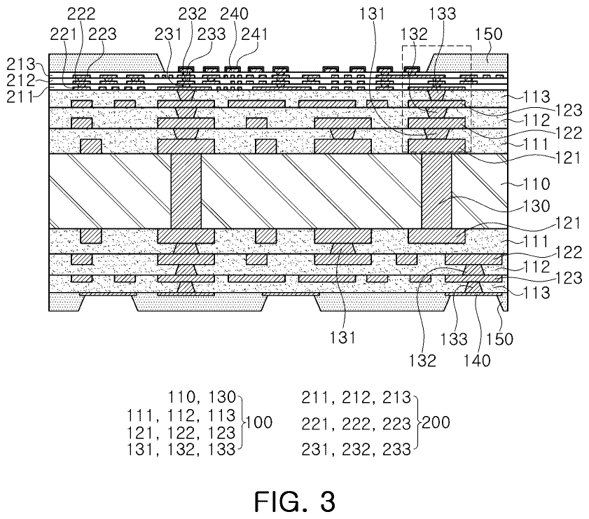

FIG. 3 is a cross-sectional view schematically illustrating a printed circuit board according to an example.

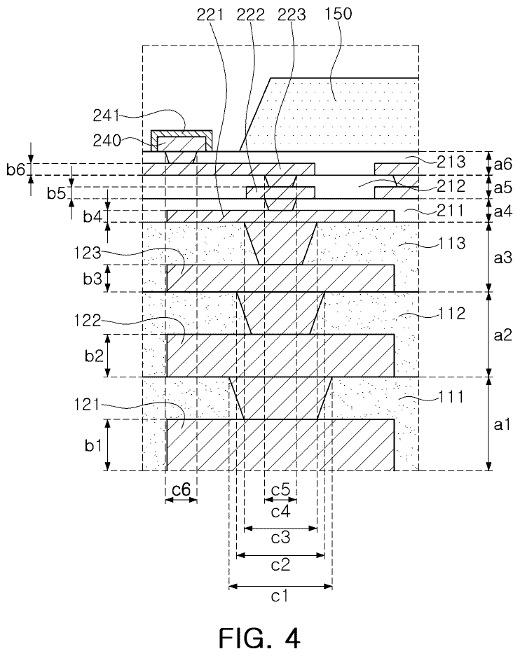

FIG. 4 is an enlarged cross-sectional view of a portion of the printed circuit board of FIG. 3.

Referring to FIG. 3, a printed circuit board according to an example includes a first substrate portion 100 and a second substrate portion 200. The first substrate portion 100 is a part that implements the signal path of the printed circuit board, and the second substrate portion 200 corresponds to a part that connects the first substrate portion 100 and components disposed on the printed circuit board. The second substrate portion 200 is a part that implements a fine signal path through a buffer role, and corresponds to a part for stably maintaining a relatively finer chip configuration and electrical signal path than the first substrate portion 100.

The first substrate portion 100 includes a core layer 110, a first insulating layer 111 disposed on the core layer 110, a second insulating layer 112 disposed on the first insulating layer 111, and a third insulating layer 113 disposed on the second insulating layer 112, and may include a first circuit 121 disposed on the core layer 110, a second circuit 122 disposed on the first insulating layer 111, and a third circuit 123 disposed on the second insulating layer 112.

The core layer 110 may include an insulating material. The insulating material may include thermosetting resins such as epoxy resins, thermoplastic resins such as polyimide, or materials containing inorganic fillers, organic fillers, and/or glass fibers (Glass Fiber, Glass Cloth, and/or Glass Fabric) together with these resins and may be a photosensitive material and/or a non-photosensitive material.

As the insulation material, Solder Resist (SR), Ajinomoto Build-up Film (ABF), FR-4, Bismaleimide Triazine (BT), Resin Coated Copper (RCC) insulation materials, and Copper Clad Laminate (CCL) insulation materials may be used as insulation materials, but the present disclosure is not limited thereto, and other polymer materials may be included. On the other hand, those resins containing inorganic fillers such as silica and reinforcing materials such as glass fibers may be used. For example, prepreg may be used, but is not limited thereto. In addition, although the core layer 110 is expressed as one layer in FIG. 3, it is not limited thereto, and a plurality of thin cores may be stacked to form the core layer 110.

The first insulating layer 111, the second insulating layer 112, and the third insulating layer 113 may include an insulating material. As the insulating material of the first insulating layer 111, the second insulating layer 112, and the third insulating layer 113, one of the same group of insulating materials as the insulating material of the core layer 110 may be selected, but the present disclosure is not limited thereto, and any material that may be used as an insulating material for a printed circuit board may be selected. The first insulating layer 111, the second insulating layer 112, and the third insulating layer 113 may include the same insulating material, but are not limited thereto, and may include different materials.

Meanwhile, in FIGS. 3 and 4, the first insulating layer 111, the second insulating layer 112, and the third insulating layer 113 are described as one insulating layer, respectively. Although the first substrate portion 100 described as being comprised of three insulating layers, it is not limited thereto. The first substrate portion 100 may further include a plurality of insulating layers each having a thickness of the insulating layer, and the lower side of the first insulating layer 111 is larger than the first insulating layer. The number of insulating layers of the first substrate portion 100 is not limited, such that a thicker insulating layer may be further included.

The first substrate portion 100 of the printed circuit board according to an example may include a first circuit 121, a second circuit 122, and a third circuit 123. The first circuit 121 may be disposed on the upper side of the core layer 110, which is synonymous with being disposed on the lower side of the first insulating layer 111. The second circuit 122 is disposed on the first insulating layer 111, and the third circuit 123 is disposed on the second insulating layer 112.

The first circuit 121, the second circuit 122, and the third circuit 123 each include a metal material. Metal materials include copper (Cu), aluminum (Al), silver (Ag), tin (Sn), gold (Au), nickel (Ni), lead (Pb), titanium (Ti), and/or alloys thereof, and may preferably include copper (Cu), but is not limited thereto. Each circuit may be a circuit pattern for a general signal path, and may perform various functions according to the design, such as mounting parts. For example, it may include a ground pattern, a power pattern, a signal pattern, and the like. In this case, the signal pattern may mean including patterns for electrical connection of various signals other than ground and power, for example, data signals. The first circuit 121, the second circuit 122, and the third circuit 123 may be formed of a plurality of circuit patterns, may be formed of a metal plate, or may be formed of a plurality of circuit patterns and a metal plate together.

The first circuit 121, the second circuit 122, and the third circuit 123 are formed by any one of a Semi Additive Process (SAP), a Modified Semi Additive Process (MSAP), Tenting (TT) or subtractive method may be, but is not limited thereto, and any method capable of configuring a circuit on a printed circuit board may be used without limitation.

Meanwhile, in FIGS. 3 and 4, the first circuit 121, the second circuit 122, and the third circuit 123 are depicted as one circuit layer, so that the first substrate portion 100 has three circuits. Although described as being comprised of layers, it is not limited thereto, and may further include a plurality of circuit layers having respective circuit layer thicknesses, and a circuit layer thicker than the first circuit layer under the first circuit 121. The number of circuit layers of the first substrate portion 100 is not limited, and may have the same number of layers as the number of insulating layers.

The first substrate portion 100 of the printed circuit board according to an example may further include a first pad 140. The first pad 140 may be used as a means for electrically connecting a printed circuit board to a main board, etc., and may be disposed on the outermost layer of the first board unit 100. The first pad 140 may be disposed on the third insulating layer and exposed to the outside. The first circuit 121, the second circuit 122, and the third circuit 123 may be made of the same material and the same method, and may perform the same function, but are not limited thereto. Meanwhile, although not illustrated in FIG. 3, a surface treatment layer may be further included on the exposed portion of the first pad 140.

The printed circuit board according to an example may further include a solder resist layer 150 as an outermost layer. The solder resist layer 150 may protect the printed circuit board from the outside, may be disposed on the lowermost side of the first substrate portion 100, and may also be disposed on the uppermost side of the second substrate portion 200. The solder resist layer 150 includes a thermosetting resin and an inorganic filler dispersed in the thermosetting resin, but may not include glass fibers. The insulating resin may be a photosensitive insulating resin, and the filler may be an inorganic filler and/or an organic filler, but is not limited thereto. However, the material of the solder resist layer 150 is not limited thereto, and other polymer materials may be used if necessary. The solder resist layer 150 may include an opening, and through the opening, the first pad 140 may be exposed to the outside and connected to other components.

The first substrate portion 100 of the printed circuit board according to an example includes a first via 131 penetrating through the first insulating layer 111 to connect the first circuit 121 and the second circuit 122 to each other, The second via 132 penetrating through the second insulating layer 112 to connect the second circuit 122 and the third circuit 123 to each other, and a third via 133 passing through the third insulating layer 113 to connect the third circuit 123 and the second substrate portion 200 may be further included.

Each of the first via 131, the second via 132, and the third via 133 includes a metal material. The metal material may be selected from among metal materials of the same group as the metal materials of the first circuit 121, the second circuit 122, and the third circuit 123, but is not limited thereto. Any material that may be used as a metal material may be selected. The first via 131, the second via 132, and the third via 133 may be formed by the same method as the first circuit 121, the second circuit 122, and the third circuit 123. However, it is not limited thereto.

As the first circuit 121, the second circuit 122, and the third circuit 123 may include a plurality of circuit patterns, the first via 131, the second via 132, and the third via 133 may include a plurality of vias. Each via may perform various functions according to the design as described above in the first circuit 121, the second circuit 122, and the third circuit 123.

On the other hand, since there is no limit to the number of insulating layers and the number of circuit layers as described above, the number of vias penetrating through the insulating layer to connect between circuit layers is also not limited to the number of layers.

The first substrate portion 100 of the printed circuit board according to an example may further include through-vias 130. The through-via 130 penetrates the core layer 110 and corresponds to a configuration for connecting the first circuits 121 disposed on both sides of the core layer 110 to each other, and the same description may be applied, but is not limited thereto, and various structures may be applied depending on the thickness and material of the core layer 110. In FIG. 3, for convenience, the through-via 130 is illustrated as filling a through-hole penetrating through a core, but the through-via 130 is not limited thereto, and the through-via may be completed by covering the side surface of the through-hole, plating the wall surface of the through-hole, and then filling the through-via with another material. For example, the shape of the through-via 130 is not limited, and any structure that penetrates the core layer and connects the first circuits 121 disposed on both sides of the core layer 110 to each other may be used without limitation.

The second substrate portion 200 of the printed circuit board according to an example includes a first fine insulating layer 211, a second fine insulating layer 212, and a third fine insulating layer 213. The second substrate portion 200 of the printed circuit board according to an example further includes a first microcircuit 221 disposed under the first fine insulating layer 211, a second microcircuit 222 disposed on the first fine insulating layer 211, and a third microcircuit 223 disposed on the second fine insulating layer 212.

The first fine insulating layer 211, the second fine insulating layer 212, and the third fine insulating layer 213 may include an insulating material. The insulating material may include thermosetting resins such as epoxy resins, thermoplastic resins such as polyimide, or materials containing inorganic fillers, organic fillers, and/or glass fibers (Glass Fiber, Glass Cloth, and/or Glass Fabric) together with these resins. It may include, and may be a photosensitive material and/or a non-photosensitive material. Insulation materials include Solder Resist (SR), Ajinomoto Build-up Film (ABF), FR-4, Bismaleimide Triazine (BT), Resin Coated Copper (RCC) insulation, Copper Clad Laminate (CCL) insulation or Photo Imagable Dielectric (PID) may be used, but is not limited thereto, and other polymer materials may be included. On the other hand, those resins containing inorganic fillers such as silica and reinforcing materials such as glass fibers may be used. For example, prepreg may be used, but is not limited thereto. Meanwhile, when PID materials are used as the first fine insulating layer 211, the second fine insulating layer 212, and the third fine insulating layer 213, it may be easy to implement a microcircuit.

The first insulating layer 111, the second insulating layer 112, and the third insulating layer 113 may include the same insulating material, but are not limited thereto, and may include different materials.

Since the second substrate portion 200 implements a finer circuit pattern than the first substrate portion 100, the first fine insulating layer 211, the second fine insulating layer 212, and the third fine insulating layer 213 may include an insulating material more advantageous to microfabrication than the first insulating layer 111, the second insulating layer 112, and the third insulating layer 113. For example, the inorganic filler contained in the first fine insulating layer 211, the second fine insulating layer 212, and the third fine insulating layer 213 is the first insulating layer 111, the second insulating layer 112, and may be finer than the inorganic filler contained in the third insulating layer 113. For example, the inorganic filler included in the insulating layer of the first substrate portion 100 may have an average diameter of 0.5 μm or more, and the inorganic filler included in the fine insulating layer of the second substrate portion 200 may have an average diameter of 0.1 μm or less. It may have an average diameter of, but is not limited thereto. The diameter may be measured using a scanning microscope or an optical microscope based on the polished or cut cross section of the printed circuit board, and the average value may be compared with the average value of values measured at five random points. For example, the first fine insulating layer 211, the second fine insulating layer 212, and the third fine insulating layer 213 in which the relatively small via hole is formed are the first fine insulating layer 211 in which the relatively large size via hole is formed. An inorganic filler having a relatively smaller size than the insulating layer 111, the second insulating layer 112, and the third insulating layer 113 may be included. However, it is not necessarily limited thereto, and the fine insulating layer of the second substrate 200 and the insulating layer of the first substrate 100 may include the same insulating material.

Each of the first microcircuit 221, the second microcircuit 222, and the third microcircuit 223 includes a metal material. Metal materials include copper (Cu), aluminum (Al), silver (Ag), tin (Sn), gold (Au), nickel (Ni), lead (Pb), titanium (Ti), and/or alloys thereof. It may include, but may preferably include copper (Cu), but is not limited thereto. Each microcircuit may be a circuit pattern for a general signal path, and may perform various functions according to the design, such as mounting parts. For example, it may include a ground pattern, a power pattern, a signal pattern, and the like. In this case, the signal pattern may mean including patterns for electrical connection of various signals other than ground and power, for example, data signals. The first microcircuit 221, the second microcircuit 222, and the third microcircuit 223 may be formed of a plurality of circuit patterns, may be formed of a metal plate, or the plurality of circuit patterns and the metal plate may be formed together.

The first microcircuit 221, the second microcircuit 222, and the third microcircuit 223 may be formed by Semi Additive Process (SAP), Modified Semi Additive Process (MSAP), TT (Tenting) or subtractive method in any one, but is not limited thereto, and any method capable of configuring a circuit or a method capable of implementing a microcircuit on a printed circuit board may be used without limitation.

Meanwhile, in FIGS. 3 and 4, the first microcircuit 221, the second microcircuit 222, and the third microcircuit 223 are described as one circuit layer. Although the second substrate portion 200 described as being comprised of three circuit layers, it is not limited thereto. The second substrate portion 200 may further include a plurality of circuit layers having respective circuit layer thicknesses, and any one microcircuit may be omitted. The number of circuit layers of the unit 200 is not limited, and may have the same number of layers as the number of insulating layers.

The second substrate portion 200 of the printed circuit board according to an example includes a first microvia 231 penetrating through the first fine insulating layer 211 to connect the first microcircuit 221 and the second microcircuit 222 to each other and a second microvia 232 penetrating through the second fine insulating layer 212 to connect the second microcircuit 222 and the third microcircuit 223 to each other. A third microvia 233 passing through the third fine insulating layer 213 may be further included to connect a second pad 240.

Each of the first microvia 231, the second microvia 232, and the third microvia 233 includes a metal material. The metal material may be selected from metal materials of the same group as the metal materials of the first microcircuit 221, the second microcircuit 222, and the third microcircuit 223, but is not limited thereto. Any material that may be used as the metal material of the circuit board may be selected. The first microvia 231, the second microvia 232, and the third microvia 233 are connected to the first microcircuit 221, the second microcircuit 222, and the third microcircuit 223. It may be formed by the same method, but is not limited thereto.

The second substrate portion 200 may further include a second pad 240. The second pad 240 may be used as a means for electrically connecting electronic components such as chips when mounted on the printed circuit board, and may be disposed on the outermost layer of the second board unit 200. The second pad 240 may be made of the same material and the same method as the first microcircuit 221, the second microcircuit 222, and the third microcircuit 223, and may perform the same function. It is not limited thereto. The second pad 240 may be disposed on the third fine insulating layer 213 and may protrude out of the third fine insulating layer 213.

The second substrate portion 200 may further include a surface treatment layer 241 covering the protruding area of the second pad 240. The surface treatment layer 241 may include any one metal among nickel (Ni), palladium (Pd), and gold (Au), and a plurality of these metal layers may be implemented. Meanwhile, the surface treatment layer is not limited thereto and may include an organic material. The surface treatment layer 241 may improve the bonding force and signal transmission capability of the second pad 240 and a component mounted on the second pad 240, and the surface treatment layer 241, as described above, may also be disposed on the first pad 140 of the substrate portion 100.

The printed circuit board according to one example may further include a solder resist layer 150 on the second substrate portion 200, and specific features of the solder resist layer 150 are as described above, but are not limited thereto, and are not known in the art. The characteristics of the solder resist layer 150 may be included.

The first fine insulating layer 211, the second fine insulating layer 212, and the third fine insulating layer 213 correspond to build-up insulating layers, and the first microcircuit 221 and the second microcircuit 222, and the third microcircuit 223 may correspond to a build-up circuit layer. The build-up insulating layer and the build-up circuit layer may mean a configuration to be distinguished from the solder resist layer 150 and the second pad 240 among the configurations of the second substrate portion 200. Referring to FIG. 3, a solder resist layer 150 may be further disposed on the third fine insulating layer 213 of the second substrate 200, and a second pad 240 may be disposed on the third microcircuit 223. This means that more may be included. At this time, the fact that the fine insulating layer and the microcircuit layer may include a larger number of insulating layers and circuit layers means that the fine insulating layer and the microcircuit layer have a larger number of insulating layers as the build-up insulating layer and the build-up circuit layer.

The third fine insulating layer 213 may correspond to a build-up insulating layer disposed on the uppermost side of the second substrate portion 200, and the third microcircuit 223 is the uppermost part of the second substrate portion 200. It may correspond to the build-up circuit layer disposed on the side. For example, it may be understood that the second substrate portion 200 includes the third fine insulating layer 213 as the build-up insulating layer on the uppermost side and the third microcircuit 223 as the build-up circuit layer on the uppermost side.

Referring to FIG. 4, the thickness a1 of the first insulating layer 111, the thickness a2 of the second insulating layer 112, and the thickness a3 of the third insulating layer 113 are sequentially reduced. For example, the thickness (a3) of the third insulating layer 113 may be lower than the thickness (a2) of the second insulating layer 112, and the thickness (a2) of the second insulating layer 112 may be lower than the thickness (a1) the first insulating layer 111.

In the present disclosure, the thickness of a certain component is a concept including an approximate one, and may be interpreted as a distance vertically crossing the upper and lower surfaces of a certain component, but may include measurement errors or errors in the manufacturing process. For example, the thickness a1 of the first insulating layer 111 may mean the distance between the upper surface of the first insulating layer 111 and the lower surface of the first insulating layer 111.

The first insulating layer 111 having a thickness a1, the second insulating layer 112 having a thickness a2, and the third insulating layer 113 having a thickness a3 are sequentially reduced to help improve bonding strength between the first substrate portion 100 and the second substrate portion 200. Since the difference in thickness between the insulating layer of the first substrate 100 and the fine insulating layer of the second substrate 200 is large, at the portion at which the first substrate 100 and the second substrate 200 are connected, there is a possibility that contact reliability may be lowered at the interface between the insulating layers. The first insulating layer 111 having a thickness a1 of the first insulating layer 111, the second insulating layer 112 having a thickness a2, and the third insulating layer 113 having a thickness a3 are sequentially reduced, if the second insulating layer 112 and the third insulating layer 113 are disposed, the stress concentrated at the interface between the first substrate portion 100 and the second substrate portion 200 is the first insulating layer 111, the second insulating layer 112, and the interface between the third insulating layer 113, respectively. Therefore, there is an effect of reducing stress at the interface between the insulating layer of the first substrate portion 100 and the fine insulating layer of the second substrate portion 200.

A thickness a4 of the first fine insulating layer 211, a thickness a5 of the second fine insulating layer 212, and a thickness a6 of the third fine insulating layer 213 may be substantially the same.

In the present disclosure, being substantially the same is a concept including approximate, and may include, for example, process errors or positional deviations occurring in the manufacturing process, errors during measurement, and the like. For example, the fact that the thickness of a certain component may be substantially the same may be understood to include not only that the thickness of a certain component is the same as that of another component, but also that the thickness is similar even if some errors are included in the measurement and manufacturing steps. The ratio of the thickness a4 of the first fine insulating layer 211, the thickness a5 of the second fine insulating layer 212, and the thickness a6 of the third fine insulating layer 213, respectively, has a lower value compared to the ratio of the thickness (a1) of the first insulating layer 111, the thickness (a2) of the second insulating layer 112, and the thickness (a3) of the third insulating layer 113, respectively.

In addition, in the present disclosure, the fact that the thicknesses of the first to third components may be substantially the same includes that the thicknesses of the first to third components are the same within an error range, as well as a meaning of excluding sequential changes. The thickness a4 of the first fine insulating layer 211, the thickness a5 of the second fine insulating layer 212, and the thickness a6 of the third fine insulating layer 213 are substantially the same. The thickness (a4) of the fine insulating layer 211, the thickness (a5) of the second fine insulating layer 212, and the thickness (a6) of the third fine insulating layer 213 are the difference in error due to the measurement process or manufacturing process. It may include the meaning of excluding sequentially decreasing to exceed. For example, the thickness a4 of the first fine insulating layer 211 is the largest, the thickness of the third fine insulating layer 213 is the smallest, and the thickness a5 of the second fine insulating layer 212 is an intermediate value between the thickness a4 of the first fine insulating layer 211 and the thickness a6 of the third fine insulating layer 213 (a4>a5>a6), and the first fine insulating layer 213 is excluded. The thickness a4 of the layer 211 is the largest, the thickness a5 of the second fine insulating layer 212 is the smallest, and the thickness a6 of the third fine insulating layer 213 is between them. It is possible to include the case of having any value of (a4>a6>a5).

Meanwhile, the thickness a4 of the first fine insulating layer 211 may be lower than the thickness of the third insulating layer 113. Since the microcircuit of the second substrate 200 has a finer structure than the circuit of the first substrate 100, the fine insulating layer of the second substrate 200 is thinner and finer in order to implement a finer circuit.

The fine insulating layer of the second substrate portion 200 is lower and uniformly formed than the insulating layer of the first substrate portion 100. The thickness a4 of the first fine insulating layer 211, the thickness a5 of the second fine insulating layer 212 and the thickness a6 of the third fine insulating layer 213 are substantially the same, or the thickness a4 of the first fine insulating layer 211 and the thickness a5 of the second fine insulating layer 213 are substantially the same. The thickness a4 of the first fine insulating layer 211, the thickness a5 of the second fine insulating layer 212, and the thickness a6 of the third fine insulating layer 213 may be lower than the thickness a1 of the first insulating layer 111, the thickness a2 of the second insulating layer 112, and the thickness a3 of the third insulating layer 113. In particular, since the second substrate portion 200 may be disposed on the outermost side of the printed circuit board, the fine insulating layer disposed on the outermost side of the printed circuit board may be formed thinner than the insulating layer of the first substrate portion 100.

Referring to FIG. 4, the thickness b1 of the first circuit 121, the thickness b2 of the second circuit 122, and the thickness b3 of the third circuit 123 may be sequentially reduced. For example, the thickness b3 of the third circuit 123 113 may be lower than the thickness b2 of the second circuit 122, and the thickness b2 of the second circuit 122 is may be lower than the thickness b1 of the third circuit 121.

The thickness b1 of the first circuit 121, the thickness b2 of the second circuit 122, and the thickness b3 of the third circuit 123 are sequentially reduced so that when the second circuit 122 and the third circuit 123 are disposed, it may be helpful to improve bonding force between the first substrate portion 100 and the second substrate portion 200. A thickness a1 of the first insulating layer 111, a thickness a2 of the second insulating layer 112, and a thickness a3 of the third insulating layer 113 are sequentially reduced, and the first circuit 121, the second circuit 122, and the third circuit 123 disposed on the respective insulating layers may also be sequentially arranged to have a small thickness. Due to this, an effect of reducing stress at an interface between the insulating layer and the circuit of the first substrate 100 and the fine insulating layer and the microcircuit of the second substrate 200 may be obtained.

In addition, the thickness b1 of the first circuit 121, the thickness b2 of the second circuit 122, and the thickness b3 of the third circuit 123 are sequentially reduced so that when the second circuit 122 and the third circuit 123 are disposed, an undulation problem that may occur in the first substrate portion 100 may be improved. Undulation is a problem that occurs in the stacking of insulating layers, and corresponds to a problem in which bending of the insulating layer may occur as much as the thickness of the circuit. Undulation may intensify as a plurality of insulating layers are stacked, and such undulation becomes a problem in the step of disposing the second substrate portion 200 on the first substrate portion 100. In order to laminate the second substrate portion 200 on the first substrate portion 100, it is common to perform a process of flattening the upper surface of the first substrate portion 100 or to manufacture and combine a separate second substrate portion substrate. However, this process is to be accompanied by separate equipment and processes. In addition, the thickness b1 of the first circuit 121, the thickness b2 of the second circuit 122, and the thickness b3 of the third circuit 123 are sequentially reduced so that when the second circuit 122 and the third circuit 123 are disposed, undulation may be reduced, the planarization process step may be omitted or simplified, and the first substrate portion 100 and the second substrate portion 200 may be an effect that may be produced continuously.

The thickness b4 of the first microcircuit 221, the thickness b5 of the second microcircuit 222, and the thickness b6 of the third microcircuit 223 may be substantially the same. Substantially the same meaning may be understood as the above meaning.

Meanwhile, the thickness b4 of the first microcircuit 221 may be lower than the thickness b3 of the third circuit 123. Since the microcircuit of the second substrate portion 200 has a finer structure than the circuit of the first substrate portion 100, the microcircuit of the second substrate portion 200 may be implemented to be thinner and smaller than the circuit in the first substrate portion 100.

The microcircuits of the second substrate portion 200 are smaller and uniformly formed than the circuits of the first substrate portion 100. The thickness b4 of the first microcircuit 221, the thickness b5 of the second microcircuit 222, and the thickness b6 of the third microcircuit 223 are substantially the same. The thickness b4 of the first microcircuit 221, the thickness b5 of the second microcircuit 222, and the thickness b6 of the third microcircuit 223 may be lower than the thickness b1 of the first circuit 121, the thickness b2 of the second circuit 122, and the thickness b3 of the third circuit 123. In particular, since the second substrate portion 200 may be disposed on the outermost side of the printed circuit board, the microcircuit disposed on the outermost side of the printed circuit board may be formed thinner than the circuit of the first substrate portion 100.

In the printed circuit board according to an example, the circuit density of the second substrate portion 200 may be higher than that of the first substrate portion 100. Higher circuit density is a relative concept, and may mean that more circuit patterns may be included in the same area, but is not limited thereto, and may mean that finer circuits are included. For example, the first microcircuit 221, the second microcircuit 222, and the third microcircuit 223 of the second substrate portion 200 may have a thickness, line/space, pitch, and the like of the wiring relatively smaller than those of the first circuit 121, the second circuit 122, and the third circuit 123 of the first substrate portion 100. Also, the insulation distance of the microcircuits of the second substrate portion 200 may be smaller than the insulation distance between the circuit layers of the first substrate portion 100. On the other hand, the thickness, line, space, pitch, etc. may be measured using a scanning microscope or an optical microscope based on the polished or cut cross section of the printed circuit board, and if these values are not constant, the average value of the values may be compared with the average value of values measured at five points.

Referring to FIG. 4, the diameter c1 (or the width c1) of the upper surface of the first via 131, the diameter c2 (or the width c2) of the upper surface of the second via 132, and the diameter c3 of (or the width c3) the upper surface of the third via 133 are sequentially reduced. The diameter c1 (or the width c1) of the upper surface of the first via 131 may mean the diameter (the width) of the upper surface of the first via 131 measured from the upper surface of the first insulating layer 111. However, in the present disclosure, the diameter of the via is not limited to having a circular top view shape of the via, and it may be understood that it corresponds to the space occupied by the upper surface of the via. For example, when the top view shape of the via is a regular polygon, it may mean twice the distance from the center of the regular polygon to the outermost point of the regular polygon. As the diameter c1 (or the width c1) of the upper surface of the first via 131, the diameter c2 (or the width c2) of the upper surface of the second via 132, and the diameter c3 (or the width c3) of the upper surface of the third via 133 sequentially decrease, the cross-sectional area of the upper surface of the first via 131, the cross-sectional area of the upper surface of the second via 132, and the cross-sectional area of the upper surface of the third via 133 may also sequentially decrease.

As the thickness a1 of the first insulating layer 111, the thickness a2 of the second insulating layer 112, and the thickness a3 of the third insulating layer 113 may be sequentially reduced, the first via 131, the second via 132, and the third via 133 penetrating through the insulating layer of may also be sequentially reduced in size. In general, as the thickness of the insulating layer increases, the diameter of the via penetrating through the insulating layer should increase, so the diameter of the via may be narrower as the thickness of the insulating layer increases. Since the first via 131, the second via 132, and the third via 133 are arranged to be sequentially smaller, the second substrate portion 200 together with the insulating layer and circuit configuration of the first substrate portion 100, and the gap between the first substrate portion 100 may be narrowed. Through this, it is possible to improve the bonding strength and flatness between the second substrate portion 200 and the first substrate portion 100.

The diameter c4 (or the width c4) of the upper surface of the first microvia 231, the diameter c5 (or the width c5) of the upper surface of the second microvia 232, and the diameter c6 (or the width c6) of the upper surface of the third microvia 233 may be substantially the same. The diameter of the upper surface of the microvias may be interpreted as the same as the diameter of the upper surface of the vias described above, and the meaning of being substantially the same may also be understood as the above meaning.

Meanwhile, the diameter c4 of the upper surface of the first microvia 231 may be narrower than the diameter c3 of the upper surface of the third via 133. Since the microcircuit of the second substrate 200 has a finer structure than the circuit of the first substrate 100, the microvias of the second substrate 200 are formed in order to implement a microcircuit. 100) may be implemented to be thinner and smaller than vias.

The microvias of the second substrate portion 200 are smaller and more uniformly formed than the vias of the first substrate portion 100. The upper surface diameter c4 of the first microvias 231, and the diameter c5 of the upper surface of the second microvias 232, and the diameter c6 of the upper surface of the third microvia 233 are substantially the same. The diameter c4 of the upper surface of the first microvia 231, the diameter c5 of the upper surface of the second microvia 232, and the diameter c6 of the upper surface of the third microvia 233 may be narrower than the diameter c1 of the upper surface of the first via 131, the diameter c2 of the upper surface of the second via 132, and the diameter c3 of the upper surface of the third via 133. In particular, since the second substrate portion 200 may be disposed on the outermost side of the printed circuit board, the minute vias disposed on the outermost side of the printed circuit board may be smaller than the vias of the first substrate portion 100.

Meanwhile, referring to FIG. 3, the first substrate portion 100 of the printed circuit board according to an example may have a symmetrical structure. At this time, the symmetrical structure does not mean that it has a completely identical design, but means that each component that may correspond to the components of the printed circuit board may be arranged. For example, in the first substrate portion 100, insulating layers, circuits, and vias may be disposed on the upper and lower surfaces of the core layer 110, respectively, and these may correspond to configurations that are symmetrical to each other. At this time, the number of insulating layers, circuits, and vias is not limited to that illustrated in FIG. 3, and may be comprised of a plurality of layers, and the number of layers may not be symmetrical.

Description of the first insulating layer 111, the second insulating layer 112, and the third insulating layer 113 laminated on the upper surface of the core layer 110 may be applied to the first insulating layer 111, the second insulating layer 112, and the third insulating layer 113 laminated on the lower surface of the core layer 110. The same may be applied to circuits and vias. Moreover, the magnitude relationship between each configuration may also be applied as it is.

When the thicknesses of the first insulating layer 111, the second insulating layer 112, and the third insulating layer 113 stacked on the lower surface of the core layer 110 are sequentially arranged to be small, the upper side may be laminated on the core layer 110 while the lower side may be laminated at the same time, and the process may be simplified. In addition, forming the lower side of the core layer 110 to be thin may have the effect of reducing the overall thickness of the printed circuit board.

Meanwhile, the printed circuit board according to one example is not limited to the configuration illustrated in FIGS. 3 and 4, and may further include general configurations of the printed circuit board, such as a cavity. For example, a configuration that may be used by those skilled in the art may be further included.

As forth above, a printed circuit board in which defects may be prevented may be provided.

A printed circuit board in which a signal path may be more finely implemented.

A printed circuit board having improved reliability may be provided.

In the present disclosure, the meaning of cross-section may mean a cross-sectional shape when an object is vertically cut, or a cross-sectional shape when the object is viewed from a side-view. In addition, the meaning on a plane may be a shape when the object is horizontally cut, or a plane shape when the object is viewed from a top-view or bottom-view.

In the present disclosure, upper side, upper side, upper surface, etc. are used to mean directions toward a surface on which electronic components may be mounted based on the cross section of the drawing for convenience, and lower side, lower side, lower side, etc. were used in the opposite direction. However, this is a direction defined for convenience of explanation, and of course, the scope of the claims is not particularly limited by the description in this direction.

In the present disclosure, the meaning of being connected is a concept including not only being directly connected but also being indirectly connected through an adhesive layer or the like. In addition, the meaning of being electrically connected is a concept including both physically connected and non-connected cases. In addition, expressions such as first and second are used to distinguish one component from another, and the order and/or importance of the corresponding components is not limited. In some cases, without departing from the scope of rights, the first component may be named a second component, similarly, the second element may be referred to as the first element.

The expression “one example” used in the present disclosure does not mean the same embodiments, and is provided to emphasize and describe different unique characteristics. However, the examples presented above are not excluded from being implemented in combination with features of other examples. For example, even if a matter described in a particular example is not described in another example, it may be understood as a description related to another example, unless there is a description contradicting or contradicting the matter in another example.

Terms used in this disclosure are only used to describe an example and are not intended to limit the disclosure. In this case, singular expressions include plural expressions unless the context clearly indicates otherwise.

While example embodiments have been illustrated and described above, it will be apparent to those skilled in the art that modifications and variations could be made without departing from the scope of the present disclosure as defined by the appended claims.

What is claimed is:

1. A printed circuit board comprising:
a first substrate portion including a first insulating layer, a second insulating layer disposed on the first insulating layer, and a third insulating layer disposed on the second insulating layer; and
a second substrate portion disposed on the first substrate portion and including a first fine insulating layer as a build-up insulating layer on an uppermost side of the first substrate portion and the second substrate portion,
wherein a thickness of the first insulating layer, a thickness of the second insulating layer, and a thickness of the third insulating layer are sequentially reduced, and
a thickness of the first fine insulating layer is lower than the thickness of the third insulating layer.

2. The printed circuit board of claim 1, wherein the first substrate portion further includes a first circuit disposed on a lower side of the first insulating layer, a second circuit disposed on the first insulating layer, and a third circuit disposed on the second insulating layer,
the second substrate portion further includes a first microcircuit disposed below the first fine insulating layer,
a thickness of the first circuit, a thickness of the second circuit, and a thickness of the third circuit are sequentially reduced, and
a thickness of the first microcircuit is lower than the thickness of the third circuit.

3. The printed circuit board of claim 2, wherein the second substrate portion further includes a second fine insulating layer disposed below the first fine insulating layer and a third fine insulating layer disposed below the second fine insulating layer, and
a thickness of the first fine insulating layer, a thickness of the second fine insulating layer, and a thickness of the third fine insulating layer are substantially the same.

4. The printed circuit board of claim 3, wherein the second substrate portion further includes a second microcircuit disposed below the second fine insulating layer and a third microcircuit disposed below the third fine insulating layer, and
the thickness of the first microcircuit, the thickness of the second microcircuit, and the thickness of the third microcircuit are substantially the same.

5. The printed circuit board of claim 4, wherein the first substrate portion further includes a first via penetrating through the first insulating layer to connect the first circuit and the second circuit to each other, a second via penetrating through the second insulating layer to connect the second circuit and the third circuit, and a third via penetrating through the third insulating layer to connect the third circuit and the second substrate portion, and
a width of an upper surface of the first via, a width of an upper surface of the second via, and a width of an upper surface of the third via sequentially decrease.

6. The printed circuit board of claim 5, wherein the second substrate portion further includes a first microvia penetrating through the second fine insulating layer to connect the first microcircuit and the second microcircuit, and a second microvia penetrating through the third fine insulating layer to connect the second microcircuit and the third microcircuit, and
a width of an upper surface of the first microvia is narrower than a width of the third via, and
the width of the upper surface of the first microvia and a width of an upper surface of the second microvia are substantially the same.

7. The printed circuit board of claim 2, wherein a density of the first microcircuit is greater than a density of the first to third circuits.

8. The printed circuit board of claim 1, further comprising a solder resist layer disposed on the second substrate portion and including an opening.

9. The printed circuit board of claim 8, wherein the second substrate portion further includes a second pad disposed on the first fine insulating layer, and
a portion of the second pad is exposed externally through the opening.

10. The printed circuit board of claim 9, wherein the second substrate portion further includes a surface treatment layer covering the portion of the second pad.

11. The printed circuit board of claim 1, wherein the first fine insulating layer and the first to third insulating layers include an inorganic filler, and
a size of the inorganic filler of the first fine insulating layer is narrower than a size of the inorganic filler of the first to third insulating layers.

12. The printed circuit board of claim 1, wherein the first substrate portion further includes a core layer, and
the first to third insulating layers are sequentially disposed on both sides of the core layer, respectively.

13. The printed circuit board of claim 12, wherein the first substrate portion further includes a first circuit disposed below the first insulating layer, a second circuit disposed on the first insulating layer, a third circuit disposed on the second insulating layer, and a first pad disposed on a lower surface of the first substrate portion; and
the second substrate portion further includes a first microcircuit disposed below the first fine insulating layer and a second pad disposed on the first fine insulating layer.

14. The printed circuit board of claim 13, further comprising a solder resist layer respectively disposed on an upper side of the second substrate portion and on a lower side of the first substrate portion.

15. A printed circuit board comprising:
a first substrate portion including a first circuit layer, a second circuit layer disposed on an upper layer of the first circuit layer, and a third circuit layer disposed on an upper layer of the second circuit layer; and
a second substrate portion disposed on the first substrate portion and including a first microcircuit layer as a build-up circuit layer on an uppermost side of the first substrate portion and the second substrate portion,
wherein a thickness of the first circuit layer, a thickness of the second circuit layer, and a thickness of the third circuit layer are sequentially reduced, and
a thickness of the first microcircuit layer is lower than a thickness of the third circuit layer.

16. The printed circuit board of claim 15, wherein the second substrate portion further includes a second microcircuit layer disposed on a lower layer of the first microcircuit layer, and a third microcircuit layer disposed on a lower layer of the second microcircuit layer, and
a thickness of the first microcircuit layer, a thickness of the second microcircuit layer and a thickness of the third microcircuit layer are substantially the same.

17. The printed circuit board of claim 15, wherein a density of the first microcircuit is greater than a density of the first to third circuits.

18. A printed circuit board comprising:
a first substrate portion including:
a first insulating layer, a second insulating layer disposed on the first insulating layer, and a third insulating layer disposed on the second insulating layer, and
a first via penetrating through the first insulating layer, a second via penetrating through the second insulating layer, and a third via penetrating through the third insulating layer; and
a second substrate portion disposed on the first substrate portion and including:
a first fine insulating layer as a build-up insulating layer on an uppermost side of the first substrate portion and the second substrate portion, and a second fine insulating layer disposed below the first fine insulating layer, and
a first microvia penetrating through the second fine insulating layer,
wherein a width of an upper surface of the first via, a width of an upper surface of the second via, and a width of an upper surface of the third via sequentially decrease, and
a width of an upper surface of the first microvia is narrower than the width of the upper surface of the third via.

19. The printed circuit board of claim 18, wherein the second substrate portion further includes a third fine insulating layer disposed below the second fine insulating layer and a second microvia penetrating through the third fine insulating layer, and
the width of the upper surface of the first microvia and a width of an upper surface of the second microvia are substantially the same.

20. The printed circuit board of claim 18, wherein the first fine insulating layer and the first to third insulating layers include an inorganic filler, and
a size of the inorganic filler of the first fine insulating layer is narrower than a size of the inorganic filler of the first to third insulating layers.
